(19) United States
(12) Patent Application Publication
(10) Pub. No.: US 2025/0357729 A1
(43) Pub. Date: Nov. 20, 2025

(54) SEMICONDUCTOR OPTICAL INTEGRATED DEVICE

(71) Applicant: Mitsubishi Electric Corporation, Tokyo (JP)

(72) Inventor: Hiroyuki OKAZAKI, Tokyo (JP)

(73) Assignee: Mitsubishi Electric Corporation, Tokyo (JP)

(21) Appl. No.: 18/854,669

(22) PCT Filed: Jun. 22, 2022
(86) PCT No.: PCT/JP2022/024796

§ 371 Date: Oct. 7, 2024

(51) Int. Cl. H01S 5/227; H01S 5/30

(52) U.S. Cl. CPC H01S 5/227; H01S 5/3013

(57) ABSTRACT

A semiconductor optical integrated device of the present disclosure includes: an InₓGa₁₋ₓAs_{y}P_{1-y} (0≤x≤1, 0≤y≤1) layer formed on a top surface of a semiconductor stacking and having a high-mesa ridge structure; a first nitride film formed on the InₓGa₁₋ₓAs_{y}P_{1-y} (0≤x≤1, 0≤y≤1) layer by a CVD method or an ALD method; an intermediate insulating film formed on the first nitride film and having a thickness of 5000 angstroms or more, the intermediate insulating film being composed of a polymer compound layer or an insulating film formed by the CVD method; and a second nitride film formed on the intermediate insulating film by the ALD method and having a thickness of 1000 angstroms or more.

### TECHNICAL FIELD

The present disclosure relates to a semiconductor optical integrated device having a high-mesa ridge structure and including an insulating film on a surface of semiconductor layers.

### BACKGROUND ART

In access networks, which are communication systems between relay stations and users, an electro-absorption modulator integrated laser (EML) is used as a semiconductor optical integrated device in which an electro-absorption modulator (EAM) suitable for high-speed modulation and a laser diode that outputs light of a single wavelength, such as a distributed feedback laser diode (DFB-LD or DFB laser), are integrated.

Since the semiconductor optical integrated device can be used in a high-temperature and high-humidity environment, it is generally known that a surface protective film is provided on the surface of semiconductor layers for the main purpose of ensuring humidity resistance. In the formation of the surface protective film, the surface protective film is made thicker to ensure a coverage property. The thicker surface protective film also has the effect of reducing the insulating-film capacitance of the insulating film that constitutes the surface protective film. In particular, the semiconductor optical integrated device having a high-mesa ridge structure with unevenness of 3 μm or more may require thicker films to ensure the coverage property because sidewalls of the high-mesa ridge structure have difficulty being covered. In contrast, the thicker surface protective film increases film stress, which may cause peeling and floating of the surface protective film. In addition, changes in film quality may also occur during heat treatment in the manufacturing process after the surface protective film is deposited, and thus there are concerns about peeling and floating of the surface protective film.

Japanese Laid-Open Patent Publication No. 61-112386 discloses a technique for increasing the thickness of the surface protective film with a three-layer insulating film structure. Unfortunately, the application to semiconductor optical integrated devices with a high-mesa ridge structure has not been considered, and concerns about peeling and floating of the surface protective film cannot be adequately solved.

### CITATION LIST

### Patent Document

Patent Document 1: Japanese Laid-Open Patent Publication No. 61-112386

### SUMMARY OF THE INVENTION

### Problem to be Solved by the Invention

In the case of the semiconductor optical integrated devices with the high-mesa ridge structure, it is more difficult to deposit the surface protective film on the sidewalls of the high-mesa ridge structure than on the surface of the semiconductor layers, and thus thicker surface protective film is required in order to ensure the coverage property. Furthermore, as the thickness of the surface protective film increases, the stress of the surface protective film also increases, further increasing concerns about peeling and floating of the surface protective film. Consequently, in the formation of surface protective films for the semiconductor optical integrated devices with the high-mesa ridge structure, there is a trade-off between ensuring the coverage property and concerns about peeling and floating of the surface protective film.

The present disclosure has been made to solve the above-described problems, and an object of the present disclosure is to provide a semiconductor optical integrated device with a surface protective film that has a coverage property even for a high-mesa ridge structure, while suppressing peeling and floating of the surface protective film from semiconductor layers.

### Means to Solve the Problem

A semiconductor optical integrated device includes: an InₓGa₁₋ₓAs_{y}P_{1-y} (0≤x≤1, 0≤y≤1) layer formed on a top surface of a semiconductor stacking and having a high-mesa ridge structure; a first nitride film formed on the InₓGa₁₋ₓAs_{y}P_{1-y} (0≤x≤1, 0≤y≤1) layer by a CVD method or an ALD method; an intermediate insulating film formed on the first nitride film and thickness of 5000 angstroms or more, the having a intermediate insulating film being composed of a polymer compound layer or an insulating film formed by the CVD method; and a second nitride film formed on the intermediate insulating film, the second nitride film being composed of a nitride film having a thickness of 1000 angstroms or more and formed by the CVD method or by the ALD method.

### Effect of the Invention

According to the present disclosure, the surface protective film can be formed with the first nitride film for ensuring the coverage property and the adhesiveness, the intermediate insulating film responsible for ensuring the coverage property and increasing the thickness of the surface protective film, and the second nitride film for achieving the humidity resistance. Thus, it is possible to provide the semiconductor optical integrated device having the high-mesa ridge structure with the surface protective film that has the coverage property while suppressing peeling and floating thereof.

### BRIEF DESCRIPTION OF THE DRAWINGS

FIG. 1 is a schematic diagram of an outer shape of an EML1 according to Embodiment 1;

FIG. 2 is a schematic diagram of the cross section along line A-A of a DFB-LD section 10 of the EML1 according to Embodiment 1;

FIG. 3 is a schematic diagram of a cross section along line B-B of the EAM section 20 of the EML1 according to Embodiment 1;

FIG. 4 is a schematic diagram of a cross section along line A-A of the DFB-LD section 10 of the EML1 according to Embodiment 1, showing a structure of a surface protective film;

FIG. 5 is a schematic diagram of a cross section along line B-B of the EAM section 20 of the EML1 according to Embodiment 1, showing the structure of the surface protective film;

FIG. 6 shows micrographs in the case where the surface protective film according to Embodiment 1 is applied after heat treatment and in the case where the surface protective film according to Embodiment 1 is not applied after heat treatment;

FIG. 7 is a schematic diagram of a cross section along line A-A of a DFB-LD section 10 of an EML1 according to Embodiment 2, showing a structure of a surface protective film;

FIG. 8 is a schematic diagram of a cross section along line B-B of an EAM section 20 of the EML1 according to Embodiment 2, showing the structure of the surface protective film.

### DESCRIPTION OF EMBODIMENTS

An example of the semiconductor optical integrated device according to the present disclosure is shown below. Note that it is not limited to the embodiments shown below, and can be implemented with any modification within the scope that does not depart from the gist of the present disclosure. For convenience of description, the term “CVD method” in this specification refers to “CVD method other than ALD method”.

### Embodiment 1

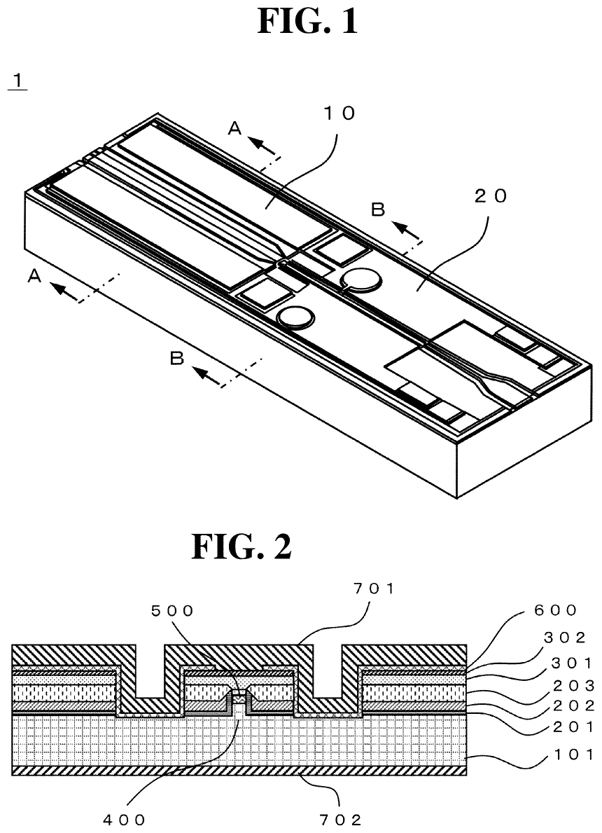

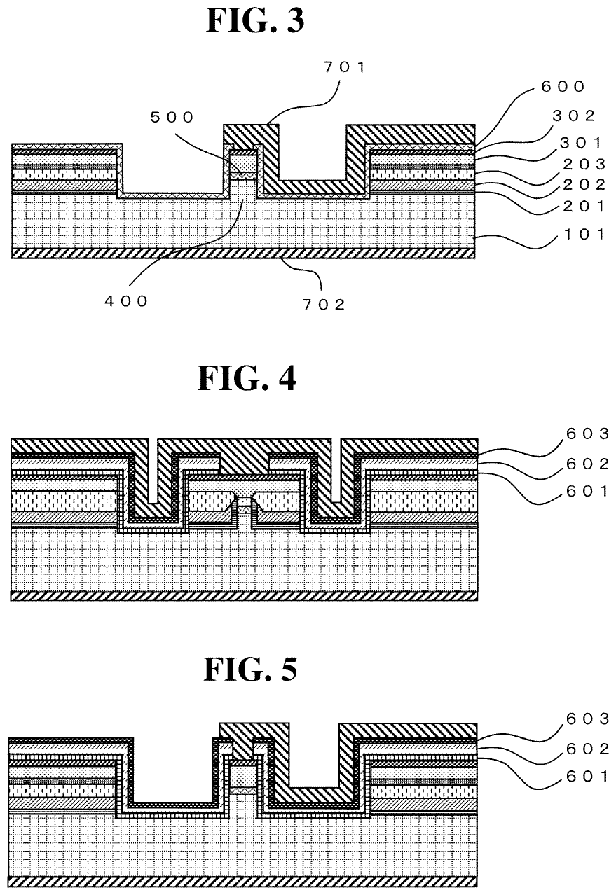

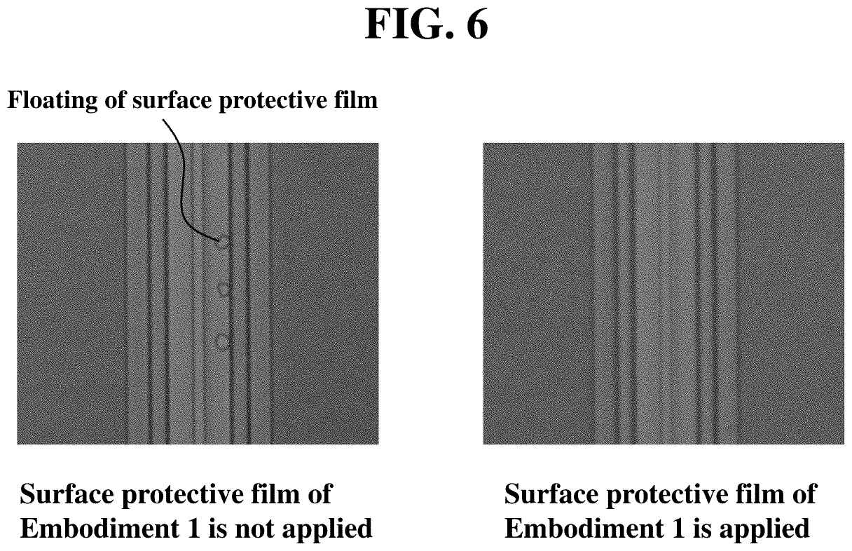

FIG. 1 is a schematic diagram of an outer shape of an EML1 according to Embodiment 1. FIG. 2 is a schematic diagram of the cross section along line A-A of a DFB-LD section 10 of the EML1 according to Embodiment 1. FIG. 3 is a schematic diagram of a cross section along line B-B of an EAM section 20 of the EML1 according to Embodiment 1. FIG. 4 is a schematic diagram of a cross section along line A-A of the DFB-LD section 10 of the EML1 according to Embodiment 1, showing a structure of a surface protective film. FIG. 5 is a schematic diagram of a cross section along line B-B of the EAM section 20 of the EML1 according to Embodiment 1, showing the structure of the surface protective film. FIG. 6 shows micrographs in the case where the surface protective according to Embodiment 1 is applied after heat treatment and in the case where the surface protective film according to Embodiment 1 is not applied after heat treatment.

In Embodiment 1, the EML1 is exemplified as the optical integrated semiconductor device. As shown in FIG. 1, the EML1 according to Embodiment 1 has the DFB-LD section 10 and the EAM section 20. As shown in FIG. 2, the DFB-LD section 10 has a cross-sectional structure in which a block layer including a p-type InP layer 201, an n-type InP layer 202, and a p-type InP layer 203 in this order from the bottom is formed on an n-type InP substrate 101. A p-type InP layer 301 and a p-type InGaAs layer 302, which constitute a contact layer, are formed on the block layer in this order from the bottom. That is, a semiconductor stacking having the block layer and the contact layer is formed above the n-type InP substrate 101. An outermost surface of the semiconductor stacking is the p-type InGaAs layer 302. In Embodiment 1, the p-type InGaAs layer 302, that is, an InₓGa₁₋ₓAs_{y}P_{1-y} (0≤x≤1, 0≤y≤1) layer in the case of y=1 is shown as the outermost surface layer of the contact layer. However, not limited to this, any InₓGa₁₋ₓAs_{y}P_{1-y} layer can be applied in the range of 0≤x≤1 and 0≤y≤1. The section of the resonator 400 has a ridge structure etched deeper than the active layer 500, that is, so-called high-mesa ridge structure. A surface protective film 600 is formed on the p-type InGaAs layer 302 to cover the surface of the p-type InGaAs layer 302. A front surface electrode 701, which is an anode electrode, is formed on the surface protective film 600. A rear surface electrode 702, which is a cathode electrode, is formed on a rear surface of the n-type InP substrate 101. As shown in FIG. 3, the EAM section 20 has the same cross-sectional structure as the DFB-LD section 10, and thus, detailed description thereof is omitted.

Next, a specific layer structure of the surface protective film 600 will be described with reference to the schematic cross-sectional view of the DFB-LD section 10 shown in FIG. 4. As shown in FIG. 4, the surface protective film 600 is formed in a three-layer structure composed of a first nitride film 601, an intermediate insulating film 602, and a second nitride film 603 in this order from the lower layer.

First, the first nitride film 601 according to Embodiment 1 is a SiN film formed by a plasma-enhanced chemical vapor deposition (PE-CVD) method, and has a thickness of 1600 angstroms. Applying SiN film formed by the PE-CVD method can cover the unevenness caused by the high-mesa ridge structure while having the adhesiveness with the semiconductor layers. Consequently, even when heat treatment is performed after the film formation, peeling and floating of the insulating film from the semiconductor layers can be suppressed. The first nitride film 601 is preferably composed of a nitride film having good adhesiveness to the semiconductor layers, and an AlN film may be applicable instead of the SiN film. As the film formation method thereof, a film formation method capable of isotropic film formation is preferable so as to cover the unevenness caused by the high-mesa ridge structure. Not only the PE-CVD method but also the chemical vapor deposition (CVD) method and the atomic layer deposition (ALD) method are also available. Furthermore, the thickness of the first nitride film 601 is preferably 500 angstroms or more such that the film can cover the unevenness due to the high-mesa ridge shape.

Next, the intermediate insulating film 602 is made of a SiO film formed by the PE-CVD method and has a thickness of 15000 angstroms. Forming the Sio film, which has a dielectric constant smaller than that of the SiN film, to a thickness of 15000 angstroms by the PE-CVD method can reduce the insulating-film capacitance while further covering the unevenness caused by the high-mesa ridge structure as in the case of the first nitride film 601. Note that the Sio film is shown as the film type of the intermediate insulating film 602, but it is sufficient that the thickness thereof is 5000 angstroms or more from the viewpoint of the coverage property and the insulating-film capacitance, and not only the Si-based oxide film but also a Si-based nitride film, an Al-based oxide film, and an Al-based nitride film can be applied as desired. As the film formation method thereof, a film formation method capable of isotropic film formation can be applied so as to cover the unevenness due to the high-mesa ridge structure, and thus, not only the PE-CVD method but also the CVD method is also available.

The second nitride film 603 is made of a SiN film formed by the PE-CVD method, and has a refractive index in the range of 1.96 to 2.00 and a thickness of 1600 angstroms. Forming the second nitride film 603 on the outermost side of the surface protective film 600 ensures the humidity resistance. The thickness of the second nitride film 603 may be as thick as required to ensure the humidity resistance. In the case of the second nitride film 603 formed by the CVD method, not limited to the PE-CVD method, and composed of a SiN film with a refractive index in the range of 1.96 to 2.00, the humidity resistance can be ensured if the film thickness is 1000 angstroms or more. In addition, in the case where the second nitride film 603 is formed by the ALD method, any Si-based or Al-based nitride film can be applied as the film type, because forming a more isotropically dense insulating film is possible compared to the CVD method. The thickness of the second nitride film 603 may be 100 angstroms or more.

FIG. 6 shows photographs of the appearance of the semiconductor optical integrated device according to Embodiment 1 and a semiconductor optical integrated device to which the technique of the comparative example is applied after heat treatment. As a comparative example, the semiconductor optical integrated device is used in which the first nitride film and the second nitride film are the same as those of Embodiment 1, but the intermediate insulating film is different from that of Embodiment 1, that is, the intermediate insulating film is composed of a Sio film which is formed by a sputtering method and has a thickness of 16000 angstroms. As can be seen from FIG. 6, in the semiconductor optical integrated device according to Embodiment 1 of the present disclosure, the surface protective film is not peeled off or floated. In contrast, in the semiconductor optical integrated device to which the technique of the comparative example is applied, a plurality of portions where the surface protective film is considered to be peeled and floated are generated. This means that even if the heat treatment is applied after the formation of the surface protective film, which tends to cause peeling and floating of the surface protective film, applying the present disclosure is effective in suppressing peeling and floating of the surface protective film.

The mechanism by which applying the present disclosure is effective in suppressing peeling and floating of the surface protective film is not necessarily clear. However, it is presumed that one of the factors is that the surface protective film is composed of a three-layer structure having the first nitride film for ensuring the coverage property and the adhesiveness, the intermediate insulating film for achieving the coverage property and increasing the thickness of the surface protective film, and the second nitride film for achieving the humidity resistance. Thereby, it is considered that the difference in thermal expansion coefficient between the semiconductors, the first nitride film, the intermediate insulating film, and the second nitride film can be absorbed. In particular, the results shown in FIG. 6 indicate that the effect of suppressing peeling and floating of the surface protective film is achieved by applying an insulating film having the coverage property not only to the first nitride film for ensuring the coverage property and the adhesiveness to the surface of the semiconductor layer and the second nitride film having humidity resistance, but also to the intermediate insulating film formed between the first nitride film and the second nitride film. This is presumed to be due to not only the difference in thermal expansion coefficient between the semiconductors, the first nitride film, the intermediate insulating film, and the second nitride film, but also to the application of the highly anisotropic sputtering method for the intermediate insulating film applied as a comparative example technology. That is, it can be estimated that the thickness of the film formed along the semiconductor layers and the thickness of the film formed on the side wall of the mesa ridge are relatively increased, and as a result, the stress generated in the semiconductors and the surface protective film cannot be absorbed, and thus the peeling and floating of the surface protective film are generated.

Applying the semiconductor optical integrated device configured such a manner allows the formation of the insulating film having the first nitride film for ensuring the coverage property and the adhesiveness, the intermediate insulating film for achieving the coverage property and increasing the film thickness of the surface protective film, and the second nitride film for achieving the humidity resistance.

Therefore, it is possible to provide a semiconductor optical integrated device having a high-mesa ridge structure with a surface protective film that has a coverage property and suppresses peeling and floating.

### Embodiment 2

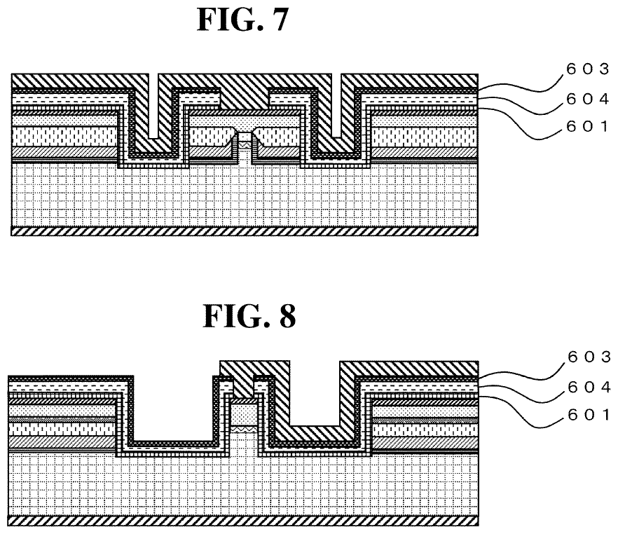

FIG. 7 is a schematic diagram of a cross section along line A-A of the DFB-LD section 10 of the EML1 according to Embodiment 2, showing the structure of the surface protective film. FIG. 8 is a schematic diagram of a cross section along line B-B of the EAM section 20 of the EML1 according to Embodiment 2, showing the structure of the surface protective film.

In Embodiment 2, as shown in FIGS. 7 and 8, the surface protective film 600 is formed in a structure in which a polyimide layer having a thickness of 15000 angstroms is used as an intermediate insulating film 604. The structure other than the intermediate insulating film 604 is the same as that in Embodiment 1, and thus a detailed description is omitted. Applying a polymer compound layer made of polyimide with a thickness of 15000 angstroms as the intermediate insulating film 604 can reduce the insulating-film capacitance while further covering the unevenness due to the high-mesa ridge structure, as in Embodiment 1. The polyimide is shown as the film type of the intermediate insulating film 604, but not limited to the polyimide, any polymer compound used as an insulating base material can be applied as long as a film thickness of 5000 angstroms or more can be formed in terms of the coverage property and the insulating-film capacitance.

Applying the semiconductor optical integration device configured in such a manner allows the formation of an insulating film having the first nitride film for ensuring the coverage property and the adhesiveness, the intermediate insulating film for achieving the coverage property and increasing the thickness of the surface protective film, and the second nitride film for achieving the humidity resistance.

Therefore, it is possible to provide a semiconductor optical integrated device having a high-mesa ridge structure with a surface protective film that has a coverage property and suppresses peeling and floating.

### DESCRIPTION OF THE REFERENCE CHARACTERS

1 EML
10 DFB-LD section
20 EAM section
101 n-type InP substrate
201 p-type InP layer
202 n-type InP layer
203 p-type InP layer
301 p-type InP layer
302 p-type InGaAs layer
400 resonator
500 active layer
600 surface protective film
601 first nitride film
602 intermediate insulating film
603 second nitride film
604 intermediate insulating film
701 front surface electrode
702 rear surface electrode

1. A semiconductor optical integrated device comprising:
an InₓGa₁₋ₓAs_{y}P_{1-y} (0≤x≤1, 0≤y≤1) layer formed on a top surface of a semiconductor stacking and having a high-mesa ridge structure;
a first nitride film formed on the InₓGa₁₋ₓAs_{y}P_{1-y} (0≤x≤1, 0≤y≤1) layer by a CVD method or an ALD method;
an intermediate insulating film formed on the first nitride film and having a thickness of 5000 angstroms or more, the intermediate insulating film being composed of a polymer compound layer or an insulating film formed by the CVD method; and
a second nitride film formed on the intermediate insulating film by the ALD method and having a thickness of 1000 angstroms or more.

2. The semiconductor optical integrated device according to claim 1, wherein the first nitride film has a thickness of 500 angstroms or more.

3. The semiconductor optical integrated device according to claim 1, wherein
the intermediate insulating film has a thickness of 15000 angstroms or more.

4. The semiconductor optical integrated device according to claim 1, wherein
the intermediate insulating film is composed of a nitride film or an oxide film formed by a PE-CVD method.

5. The semiconductor optical integrated device according to claim 1, wherein
the second nitride film is composed of a SiN film having a refractive index of 1.96 or more and 2.00 or less and a thickness of 1000 angstroms or more.

6. The semiconductor optical integrated device according to claim 1, wherein
the second nitride film is composed of a Si-based nitride film or an Al-based nitride film formed by the ALD method and has a thickness of 100 angstroms or more.

7. The semiconductor optical integrated device according to claim 2, wherein
the intermediate insulating film has a thickness of 15000 angstroms or more.

8. The semiconductor optical integrated device according to claim 2, wherein
the intermediate insulating film is composed of a nitride film or an oxide film formed by a PE-CVD method.

9. The semiconductor optical integrated device according to claim 2, wherein
the second nitride film is composed of a SiN film having a refractive index of 1.96 or more and 2.00 or less and a thickness of 1000 angstroms or more.

10. The semiconductor optical integrated device according to claim 2, wherein
the second nitride film is composed of a Si-based nitride film or an Al-based nitride film formed by the ALD method and has a thickness of 100 angstroms or more.

11. The semiconductor optical integrated device according to claim 3, wherein
the intermediate insulating film is composed of a nitride film or an oxide film formed by a PE-CVD method.

12. The semiconductor optical integrated device according to claim 3, wherein
the second nitride film is composed of a SiN film having a refractive index of 1.96 or more and 2.00 or less and a thickness of 1000 angstroms or more.

13. The semiconductor optical integrated device according to claim 3, wherein
the second nitride film is composed of a Si-based nitride film or an Al-based nitride film formed by the ALD method and has a thickness of 100 angstroms or more.

14. The semiconductor optical integrated device according to claim 4, wherein
the second nitride film is composed of a SiN film having a refractive index of 1.96 or more and 2.00 or less and a thickness of 1000 angstroms or more.

15. The semiconductor optical integrated device according to claim 4, wherein
the second nitride film is composed of a Si-based nitride film or an Al-based nitride film formed by the ALD method and has a thickness of 100 angstroms or more.
